(19) United States
(12) Patent Application Publication
(10) Pub. No.: US 2026/0173468 A1
(43) Pub. Date: Jun. 18, 2026

(54) LATERAL IDEAL DIODE FOR BANDGAP REFERENCE IN NANOSHEET TECHNOLOGY

(71) Applicant: International Business Machines Corporation, Armonk, NY (US)

(72) Inventors: Terence B. Hook, Jericho Center, VT (US); Robert Gauthier, Williston, VT (US)

(21) Appl. No.: 18/981,472

(22) Filed: Dec. 14, 2024

(51) Int. Cl. H10D 62/10; G05F 3/24; H10D 30/00; H10D 30/01; H10D 30/43; H10D 30/67; H10D 84/80

(52) U.S. Cl. CPC H10D 62/121; G05F 3/24; H10D 30/0194; H10D 30/0195; H10D 30/43; H10D 30/502; H10D 30/507; H10D 30/6735; H10D 30/6757; H10D 84/811

(57) ABSTRACT

A semiconductor structure includes a semiconductor device that includes a diode structure including: stacked nanolayers including alternating Si nanolayers and SiGe nanolayers; a p-type doped anode region in direct contact with the stacked nanolayers; and an n-type doped cathode region in direct contact with the stacked nanolayers; and a plurality of field effect transistor (FET) structures. Each FET structure comprises Si nanolayers that are coplanar with the Si nanolayers of the diode structure. The structure can be employed, at least in part, to realize a bandgap reference circuit.

### BACKGROUND

The present invention relates generally to the electrical, electronic, and computer arts, and, more particularly, to semiconductor devices including diodes.

Nanosheet architecture (channels formed from multiple thin layers of silicon gated on all four sides) is now the standard advanced technology. Backside wiring is emerging as a pertinent element to enable fuller utilization of semiconductor area. In an aggressive form of backside power delivery network (BSPDN), the bulk wafer is completely removed, leaving the transistor source and drain isolated from one another by dielectric. While this configuration has substantial advantages in reduced capacitance, the absence of punch-through current, and direct backside contact to the source and drain, there is a challenge in creating an “ideal” PN diode in the absence of a bulk silicon substrate.

### BRIEF SUMMARY

Principles of the invention provide techniques for a lateral ideal diode for bandgap reference in nanosheet technology.

In one aspect, an exemplary semiconductor structure includes a semiconductor device that comprises a diode structure including: stacked nanolayers including alternating Si nanolayers and SiGe nanolayers; a p-type doped anode region in direct contact with the stacked nanolayers; and an n-type doped cathode region in direct contact with the stacked nanolayers; and a plurality of field effect transistor (FET) structures, wherein each FET structure comprises Si nanolayers that are coplanar with the Si nanolayers of the diode structure.

In another aspect, an exemplary bandgap reference circuit includes a complementary metal oxide semiconductor operational amplifier; a field effect transistor having a first source drain terminal, a second source drain terminal, and a gate coupled to an output of the operational amplifier; and a resistor-diode network coupled to the second source drain terminal. The resistor-diode network includes a plurality of resistors and a plurality of diodes. At least one diode of the plurality of diodes includes stacked nanolayers including alternating Si nanolayers and SiGe nanolayers; a p-type doped anode region in direct contact with the stacked nanolayers; and an n-type doped cathode region in direct contact with the stacked nanolayers. The field effect transistor includes Si nanolayers that are coplanar with the Si nanolayers of the at least one diode.

In still another aspect, an exemplary method of forming a semiconductor device comprises providing an initial diode structure that includes a stack of SiGe nanolayers that are alternatively stacked with the Si nanolayers; forming a p-type anode on one side of the stack, and forming an n-type cathode on the other side of the stack; and forming a plurality of field effect transistors (FETs) in other regions of the semiconductor device, wherein each FET comprises SiGe nanolayers and Si nanolayers that are coplanar with the Si nanolayers of the initial diode structure. In one or more embodiments, the FET formation and the anode and cathode formation are carried out in parallel.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor and/or by semiconductor fabrication equipment, by sending appropriate data or commands to cause or aid the action to be performed. Where an actor facilitates an action other than by performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
A useful and effective lateral diode created along with a dielectric-isolated nanosheet transistor by a) selectively eliminating an inner spacer silicon germanium (SiGe) pullback step, and b) selectively eliminating nanosheet release etch;
Improved ideality: the ideality is adequate for some key applications such as a bandgap reference (BGR) circuit in the standard contact structure, but can be improved and better current uniformity obtained if a contact extends deeper than the top of nanosheets. Ideality, or the ratio of the current-voltage relationship in the inventive structure relative to that of a perfectly formed diode, is pertinent to area-scaling and temperature-insensitive circuits.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 illustrates a structure for a PN diode, according to an aspect of the invention.

FIG. 2 illustrates a structure similar to that of FIG. 1, but without the inner spacers.

FIG. 3 illustrates the structure of FIG. 1 with the SiGe removed and replaced with gate material.

FIG. 4 illustrates a semiconductor structure that includes a diode structure and FET structures which can coexist on the same wafer, according to an aspect of the invention.

FIG. 5 illustrates simulation results for various configurations of the field effect transistor-like structure.

FIG. 6 illustrates the current-voltage (IV) curves of the heavier-doped well of 5×10¹⁸ and the lighter asymmetric doped wells 1×10¹⁵/5×10¹⁵.

FIG. 7 illustrates tabulated data used for the curves in FIG. 8.

FIG. 8 illustrates permutations overlaid with the earlier results in FIG. 6.

FIG. 9 presents simulation results for current density distribution, from the aforementioned multidimensional device simulator for the plot in FIG. 8.

FIG. 10 illustrates results for a final configuration of the bandgap reference application.

FIG. 11 illustrates the IV characteristic of the lightly doped well superimposed upon the previous results in FIG. 8.

FIG. 12 illustrates that the current in the topmost layer of SiGe dominates.

FIG. 13 compares ideality between cases; more current in the lower layers, the total current increases, and the ideality is slightly improved.

FIGS. 14A and 14B illustrate an initial structure for a diode.

FIGS. 15A and 15B illustrate the structure of FIGS. 14A and 14B after forming recesses in the SiGe nanolayers that are alternatively stacked with the Si nanolayers.

FIGS. 16A and 16B illustrate the structure of FIGS. 15A and 15B after forming standard inner spacers in the recesses.

FIGS. 17A and 17B illustrate the structure of FIGS. 16A and 16B after forming a p-type anode on one side of the SiGe/Si stacks, and an n-type cathode on the other.

FIGS. 18A and 18B illustrate the structure of FIGS. 17A and 17B after masking, blocking, and SiGe etch.

FIGS. 19A and 19B illustrate the structure of FIGS. 18A and 18B after the SiGe etch process in the selected locations.

FIG. 20 illustrates the structure of FIGS. 19A and 19B after gate formation and bulk silicon removal and backside dielectric deposition.

FIGS. 21A and 21B illustrate an initial structure for a diode.

FIGS. 22A and 22B illustrate the structure of FIGS. 21A and 21B after formation of the p-type source-drain on one side of the SiGe/Si stacks, and the n-type source-drain on the other.

FIGS. 23A and 23B illustrate the structure of FIGS. 22A and 22B after masking, blocking, and SiGe etch.

FIGS. 24A and 24B illustrate the structure of FIGS. 23A and 23B after standard metal gate formation.

FIG. 25 illustrates the structure of FIGS. 24A and 24B after bulk silicon removal and backside dielectric deposition.

FIG. 26 illustrates an exemplary bandgap reference circuit including one or more diode structures and one or more FET structures, in accordance with aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

As noted, there is a challenge in creating PN diodes that are ideal for bandgap reference circuits. Advantageously, one or more embodiments overcome the drawbacks of the prior art by including configurations of a lateral PN diode situated on a dielectric. Embodiments include a structure with parallel sheets of Si and SiGe, with current delivered broadside from the epitaxial anode/cathode regions, and light doping in the channel region.

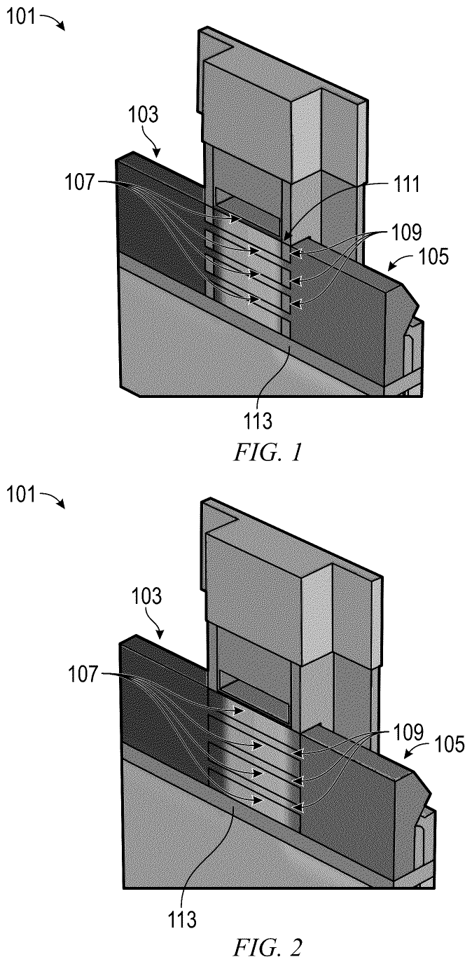

FIG. 1 illustrates a structure 101 for a PN diode. The structure 101 includes cathode 103 epitaxy, anode 105 epitaxy, SiGe nanolayers 107, Si nanolayers 109, inner spacers 111, and a substrate 113. Ends of the SiGe regions are isolated from the anode and the cathode by the conventional inner spacer required for nanosheet fabrication. Half of the structure is shown here for clarity.

FIG. 2 illustrates the structure 101 without the inner spacers. Note the cathode 103 epitaxy, the anode 105 epitaxy, the SiGe layers 107, the Si nanolayers 109, and the substrate 113. The structure includes parallel sheets of Si and SiGe, with current delivered broadside from the epitaxial anode/cathode regions and light channel doping. The SiGe and the epitaxy abut one another. This is the preferred structure for diode ideality. Half of the structure is shown here for clarity.

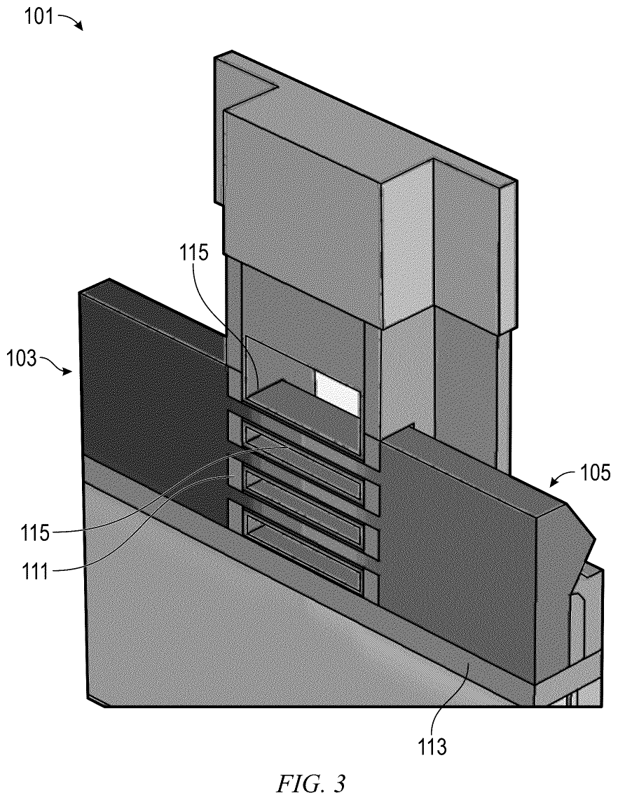

FIG. 3 illustrates the structure 101 with the SiGe removed and replaced with gate material 115. Note the cathode 103 epitaxy, the anode 105 epitaxy, the inner spacers 111, and the substrate 113. This structure closely resembles the conventional FET except that an anode and a cathode of opposite doping type are provided rather than source and a drain of the same doping type. Half of the structure is shown here for clarity.

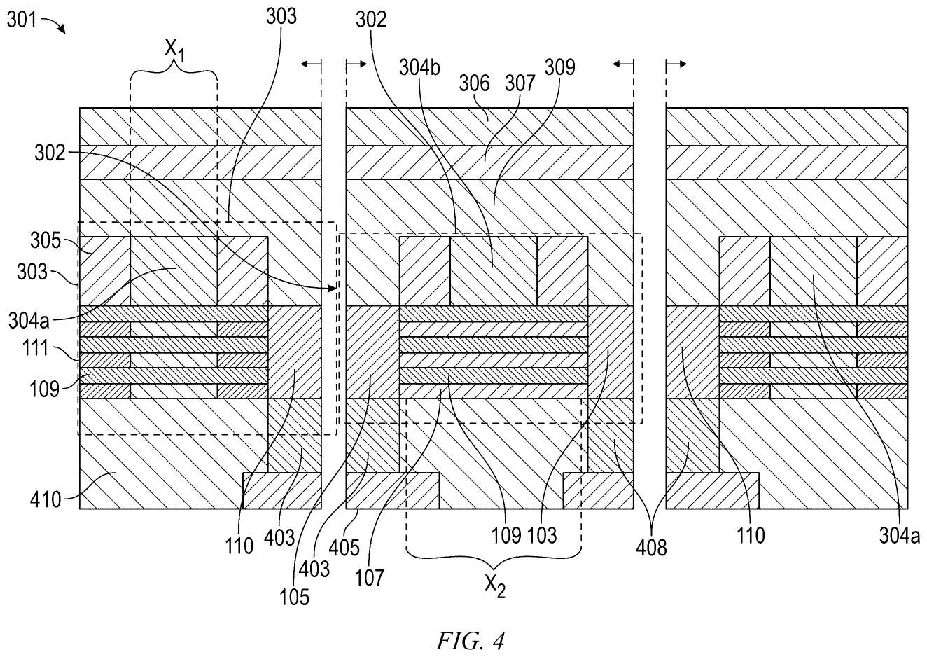

FIG. 4 illustrates a semiconductor device 301 that includes a diode structure 302 and FET structures 303 which can coexist on the same wafer; they are not necessarily adjacent to each other. The FET structures 303 include replacement metal gates 304a, Si nanolayers 109, inner spacers 111, source-drain 110 and outer spacers 305. The FETs will have two source drain regions; only one is shown for illustrative convenience. The replacement metal gates can be gate all around (GAA) structures surrounding the channels (Si nanolayers 109). Note a carrier wafer 306, a back-end-of-line layer (BEOL wiring layer 307), and interlayer dielectric (ILD 309) disposed above the diode structure 302 and FET structures 303. The diode structure 302 is shown as disposed between the FET structures 303, although as noted, adjacency is not required. The diode structure 302 includes a metal gate 304b formed on top of the Si/SiGe stack of the diode structure 302; in the example, the metal gate 304b is located only on top of the diode; i.e., it is not a GAA type structure as in the FET. The diode structure 302 includes a p-type doped epitaxially grown anode 105 region, an n-type doped epitaxially grown cathode 103 region, a backside contact 403, a backside insulator 408, the SiGe nanolayers 107, and the Si nanolayers 109. Note an insulating layer 410 that can be the same material as the ILD 309 or a different material. Note BSPDN 405 that can be connected to the backside contact 403. The BSPDN 405 can include one or more backside wiring levels including multiple components such as horizontal wires and vertical vias, and the like. The Si nanolayers 109 of the diode structure 302 are coplanar with Si active channels (e.g., the Si nanolayers 109) of the field effect transistor structures 303 in a different cell/region. One lateral dimension x₁ of the device is set by the FET metal gate process and the transistor design point. Another lateral dimension x₂ is set by the diode design point, and while it may be limited by the FET process, lithographically defined anode-cathode spacing could be the determining factor. Values for x₁ and x₂ can range from 20 nanometers to 200 nanometers. Furthermore in this regard, the diode needs to be wide enough to allow masking for the cathode doping and then masking for the anode doping (or vice-versa) while for a FET, the source and drain are both of the same dopant type and can be formed simultaneously with the gate functioning as a mask; thus, the diode will typically need to be wider than a FET.

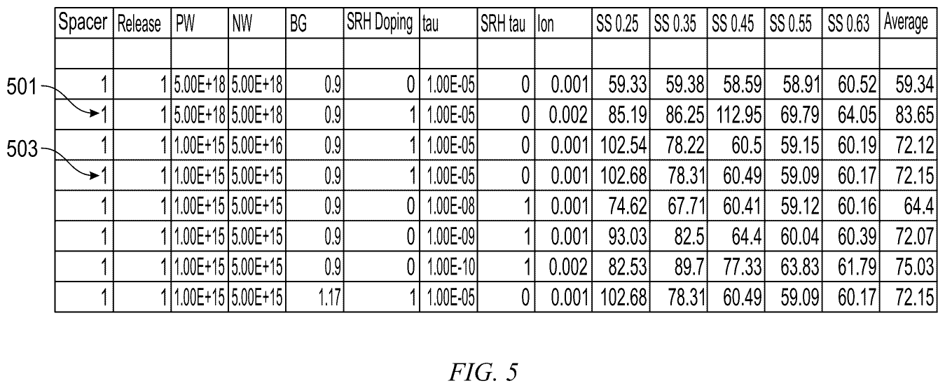

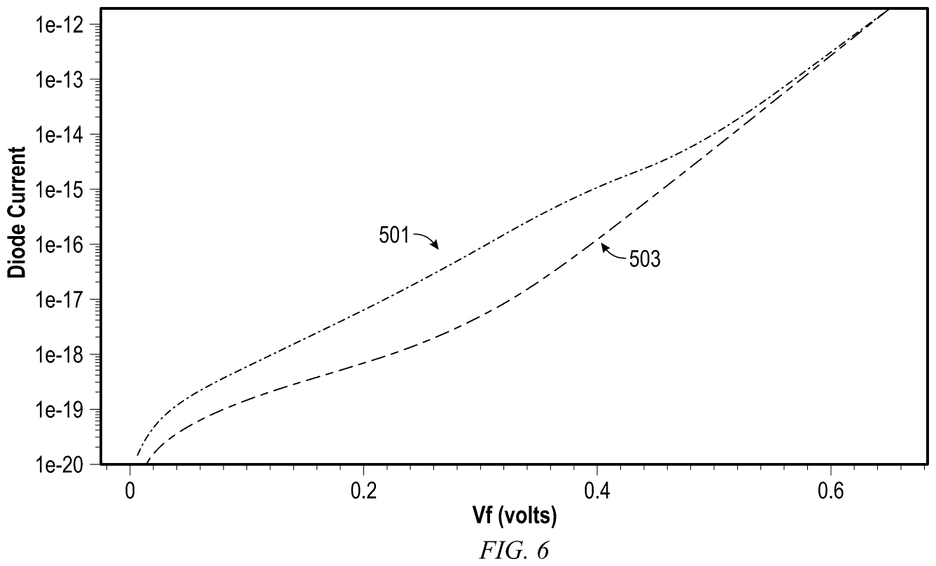

FIG. 5 illustrates simulation results for various configurations of the field effect transistor-like structure of FIG. 3. Note data in each row for a case 501 and for a case 503. The entry of “1” in the “spacer” and “release” columns indicates that these processes were executed to form the structure. The NW and PW doping level refers to the sheets (the doping in the anode and cathode contact regions is degenerate); in all cases the junction is positioned in the middle of the device. This particular set of simulations was with a “gate length” (anode/cathode spacing) of 50 nm. If the Shockley-Read-Hall “SRH doping” entry is enabled (“1”), the lifetime is calculated by a commercially-available advanced multidimensional device simulator for simulating electrical, thermal, and optical characteristics of silicon-based and compound semiconductor devices using default Scharfetter parameters; otherwise, the lifetime is as indicated by “tau,” or there is no SRH recombination at all. The current-voltage slope in mV/decade is calculated at several points of forward bias and “Ion” is the diode current at Vf=0.55V, where Vf is the forward bias voltage. Two of these curves (the case 501 and the case 503) are tabulated in FIG. 6 and discussed below.

The final entry assigns the SiGe band parameters to be the same as for silicon. As there is no SiGe in this structure, the results are identical to the corresponding entry above, basically verifying the validity of the simulation. A pertinent observation about these entries is that for none of the permutations is the ideality acceptable for bandgap reference applications, which normally requires ideality on the order of 1.05, or a slope of less than 63 mV/decade across several decades of current. In the example of the table, the only one that meets this requirement is the first, which is a physically unrealistic situation with SRH recombination turned off entirely in the simulation.

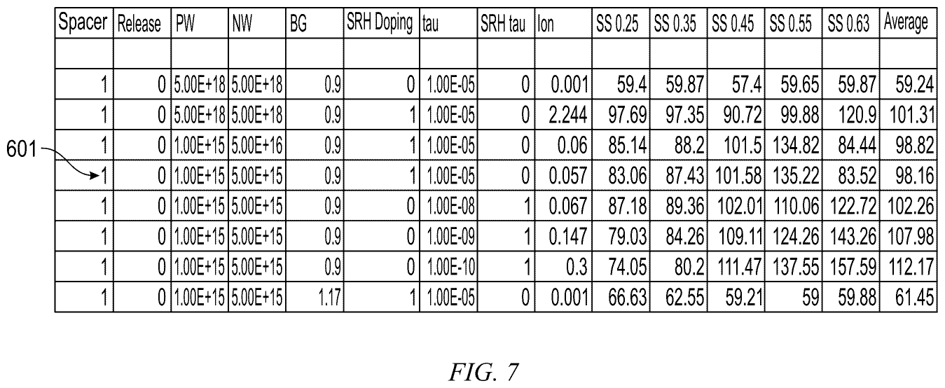

In general, higher doping means shorter SRH lifetime and degraded ideality, but this differs in the details. FIG. 6 shows the current-voltage (IV) curves of the heavier-doped well of 5×10¹⁸ (case 501) and the lighter asymmetric doped wells 1×10¹⁵/5×10¹⁵ (case 503). The transition from a region dominated by recombination is shifted to a higher current level for the higher doping, and therefore the ideality “appears” to be superior at the lower injection points. However, these results show that the structure will not produce an adequate ideality across a range of currents. Analogous variations were run for the structure that retains the SiGe sacrificial layers, but also retains the inner spacer structure. These results are summarized in FIG. 7. Once again, the overall ideality performance of this structure is undesirable—larger than 63 mV/decade. The first entry is the physically unachievable case of no SRH recombination at all, albeit with excellent ideality. The final entry is also good, but this is the physically problematic case of a block of solid silicon, with no SiGe layers. This would require a process scheme different from that employed to create the co-existing transistors.

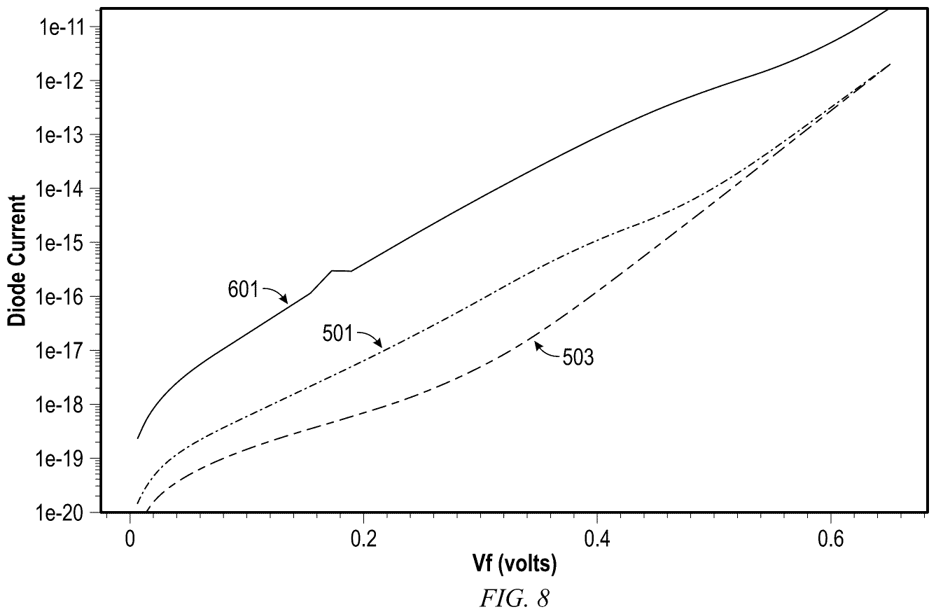

FIG. 8 illustrates that, for the rest of the permutations, the IV case 601 of the best (average 98.16) is overlaid with the earlier results in FIG. 6. The overall current is much higher—there is certainly current spreading into the SiGe portion of the stack (which was removed in the previous structure). However, the ideality is undesirably large for the bandgap reference application (>63 mV/decade) throughout and dependent on the SRH lifetime.

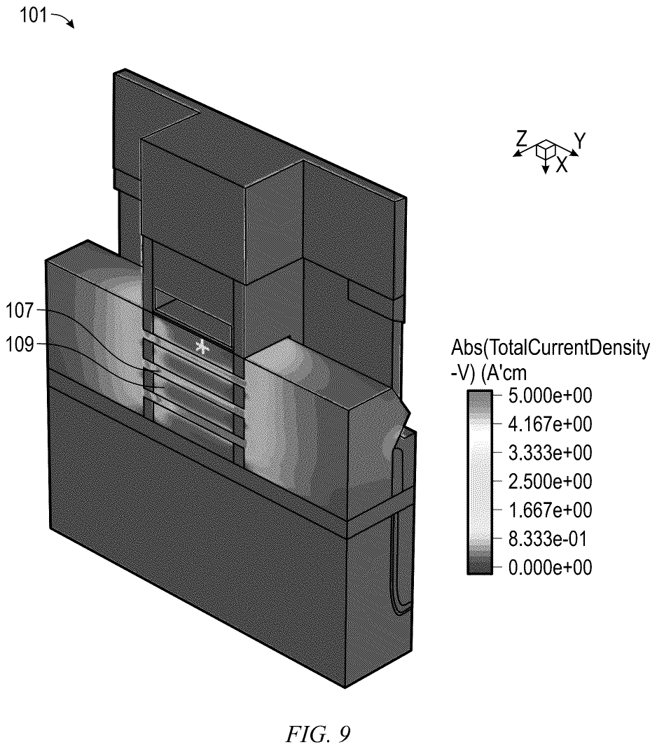

In FIG. 9, simulation results for current density distribution are presented, from the aforementioned multidimensional device simulator for the case 601 plotted in FIG. 8. While there is some spreading into the SiGe regions (SiGe nanolayers 107), the current is necked down and limited by the Si regions (Si nanolayers 109) at the ends. The variation of the spreading across the voltage range adversely affects ideality as the effective cross-sectional size of the diode changes with the current.

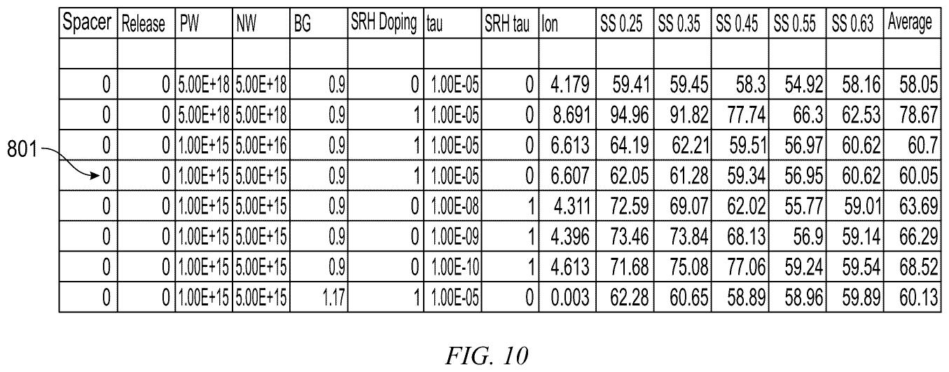

The final configuration examined is the most suitable for the bandgap reference application; the results are summarized in FIG. 10. In this structure the SiGe layer (normally sacrificial in the FET region) is retained in the diode region and the inner spacer which would otherwise block current from the anode and cathode epitaxies is not present, allowing more uniform current injection into the SiGe layer.

The first two entries show that in the (physically impossible) situation of no recombination at all that excellent ideality is obtained. Relatively heavy doping of 5×10¹⁸ degrades the ideality but acceptable numbers are found with lighter well doping. An SRH lifetime of 10 nanoseconds has marginally acceptable ideality of 1.06. The final entry, where SiGe band parameters are overridden to mimic silicon (another unphysical manifestation), shows a negligible change in ideality and a dramatic reduction in current over the equivalent doping in the bilayer version. The IV characteristic of the lightly doped well (case 801) is further superimposed upon the previous results in FIG. 11. Good ideality is obtained across a wide range of biases.

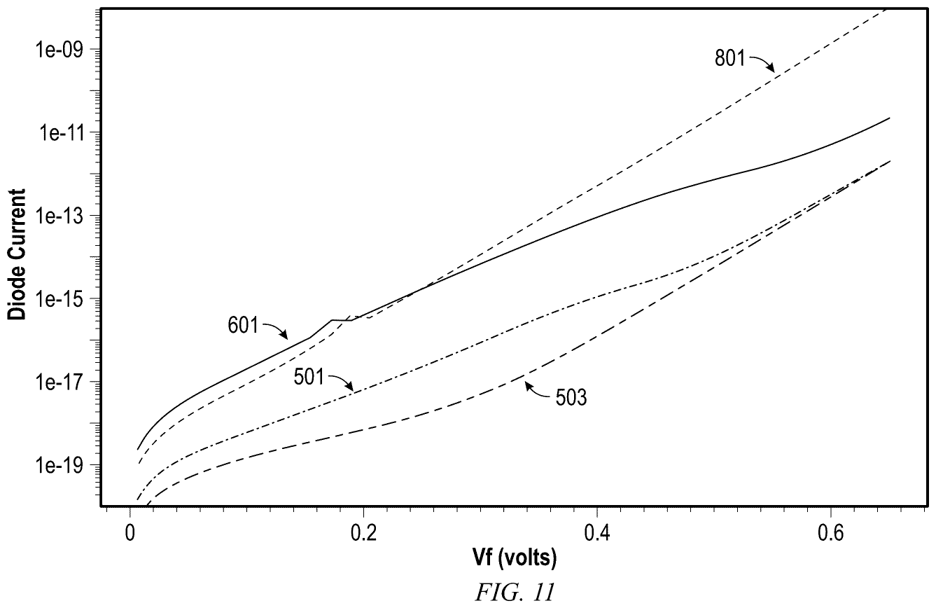

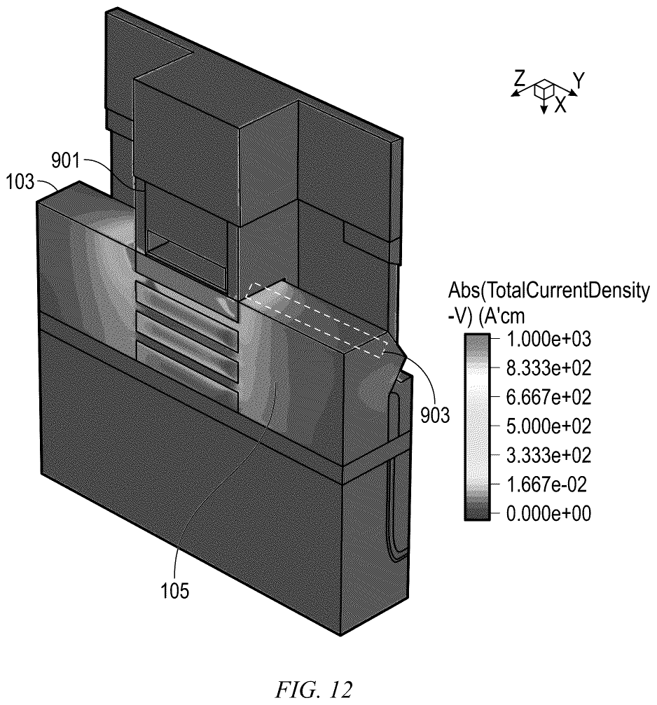

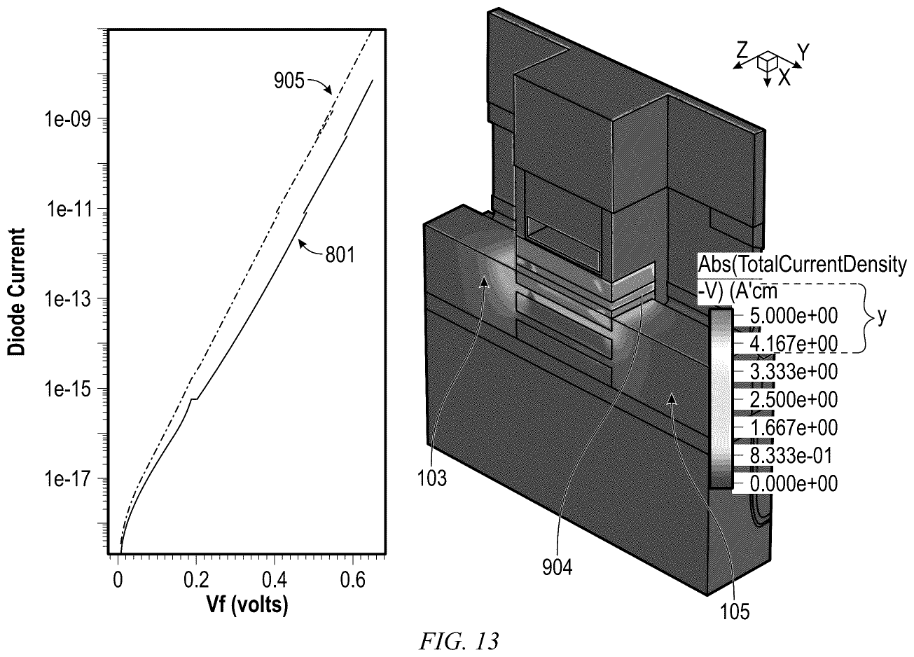

Looking at this case in more detail, FIG. 12 shows that the current in the topmost layer 901 of SiGe dominates. This is because of the near proximity to the metallic contact 903. If the contact 903 is gouged into the anode/cathode epitaxy (as in metallic contact 904 in FIG. 13), the metallic contact 904 then laterally abuts the anode 105 epitaxy (or the cathode 103 epitaxy) over at least some vertical distance y. There is now more current in the lower layers, the total current increases, and the ideality is slightly improved, as in case 905 compared with the case 801 in FIG. 13.

Finally, it can be concluded that a useful and effective lateral diode can be created along with dielectric-isolated nanosheet transistor by a) selectively eliminating the inner spacer SiGe pullback step, and b) selectively eliminating the sheet release etch and thus retaining the SiGe layers in this structure. While the ideality is adequate (e.g., 1.06) in the structure where the contact rests on the top of the anode/cathode epitaxy, it can advantageously be improved, and better current uniformity obtained, if the contact extends deeper than the top of the sheets, as in FIG. 13.

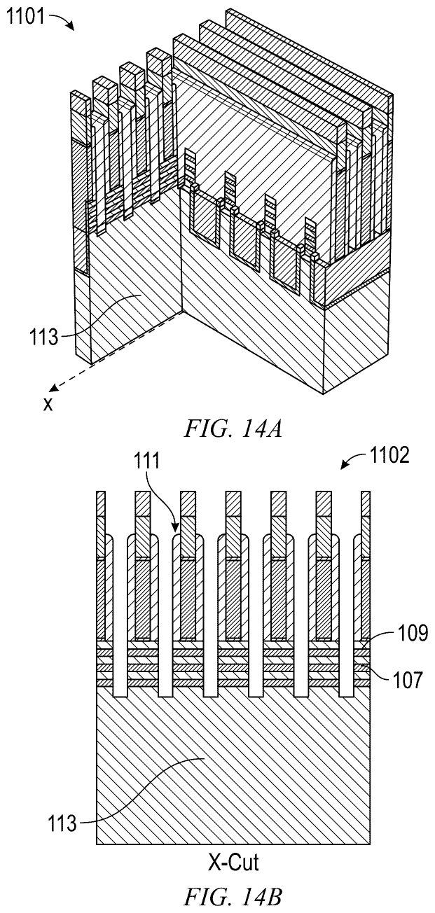

Consider now a first exemplary process flow shown in FIGS. 14A-20. Refer initially to the views in FIGS. 14A and 14B and the view along section line X. Note the standard SiGe nanolayers 107. The initial diode structure 1101 includes SiGe nanolayers 107 that are alternatively stacked with the Si nanolayers 109. Note the substrate 113 and the gate definition hardmask structure 1102, including spacer 111.

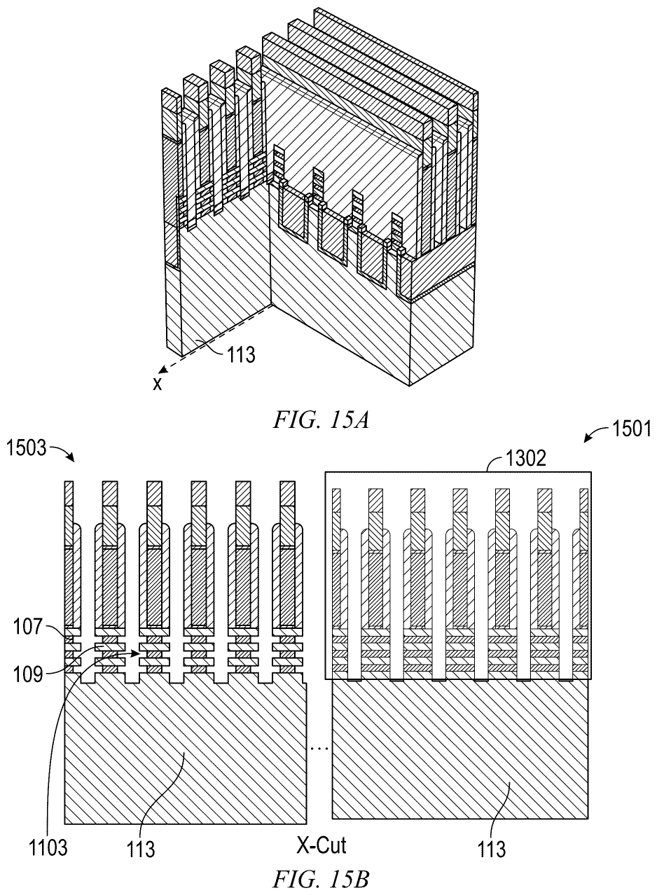

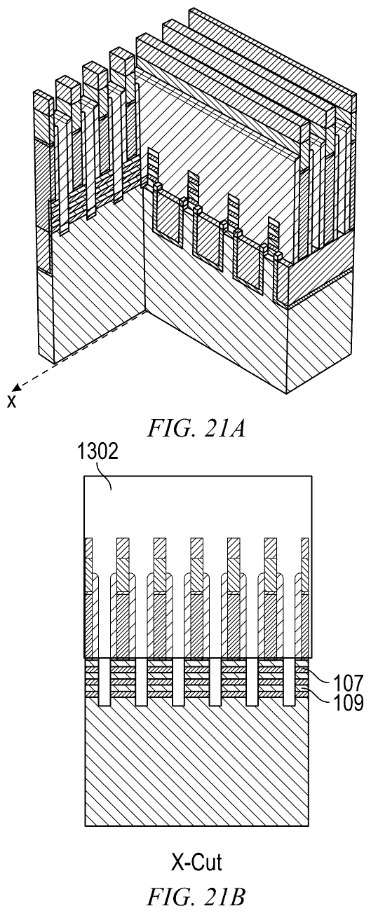

FIGS. 15A and 15B illustrate the structure of FIGS. 14A and 14B after forming recesses 1103 in the SiGe nanolayers 107 that are alternatively stacked with the Si nanolayers 109. FIG. 15B illustrates a mask 1302 that can be used in some examples to cover the SiGe nanolayers 107 and the Si nanolayers 109. That is, the mask 1302 can be used to selectively block the SiGe etch, creating regions where there is no inner spacer in the diode region 1501, while forming the inner spacer elsewhere and in the FET region 1503 (or another diode region (e.g., variant diode that does have inner spacers)), and will be further discussed with respect to FIGS. 21A-25. As indicated by the ellipsis, FIG. 15B is taken at different regions along the X cut.

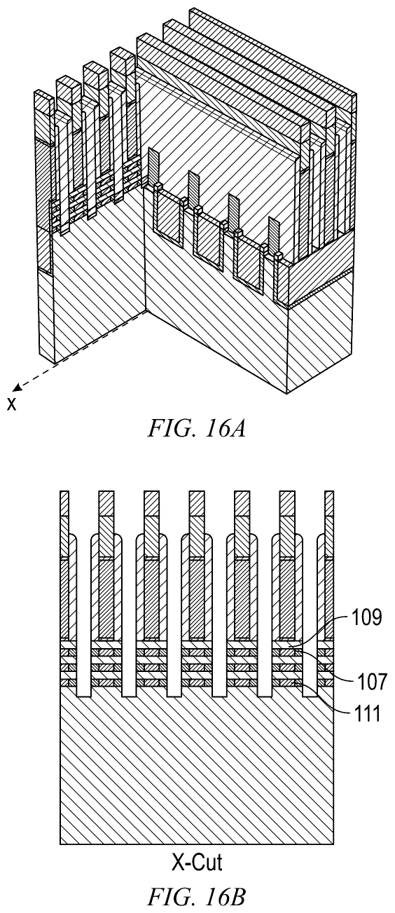

FIGS. 16A and 16B illustrate the structure of FIGS. 15A and 15B after forming standard inner spacers 111 in the recesses.

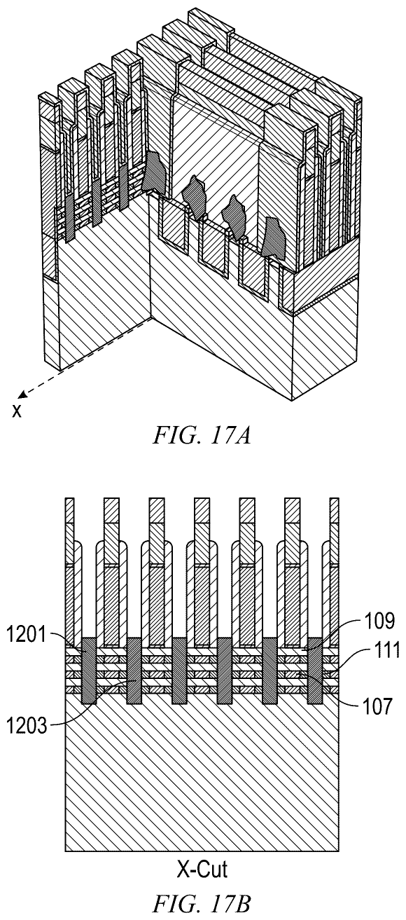

FIGS. 17A and 17B illustrate the structure of FIGS. 16A and 16B after forming a p-type anode 1201 on one side of the SiGe/Si stacks, and an n-type cathode 1203 on the other.

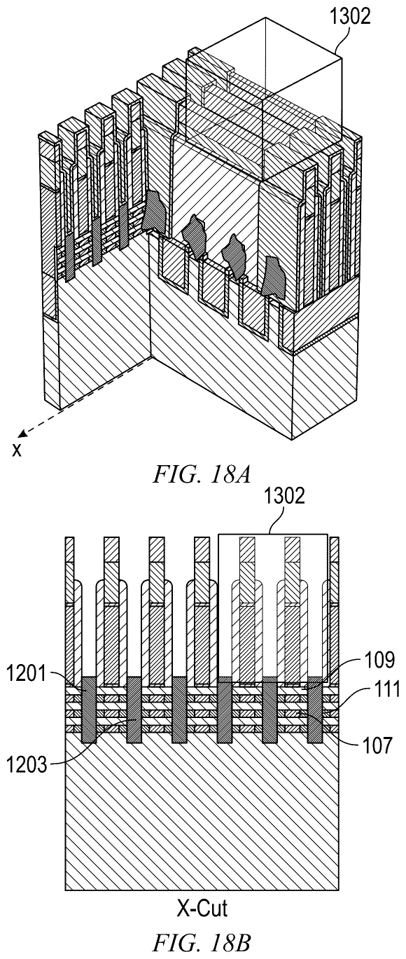

FIGS. 18A and 18B illustrate the structure of FIGS. 17A and 17B after masking, blocking, and SiGe etch. The mask 1302 can be used to selectively block the SiGe etch (or release step) in the diode region, while forming the FET in the other regions.

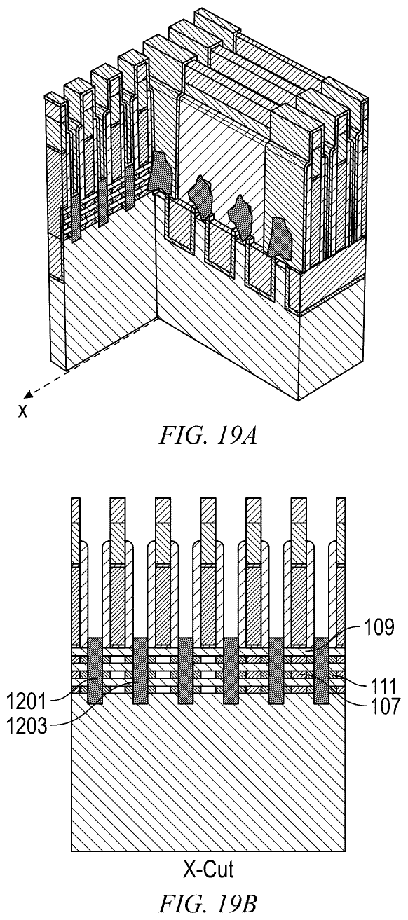

FIGS. 19A and 19B illustrate the structure of FIGS. 18A and 18B after the SiGe etch process in the selected locations.

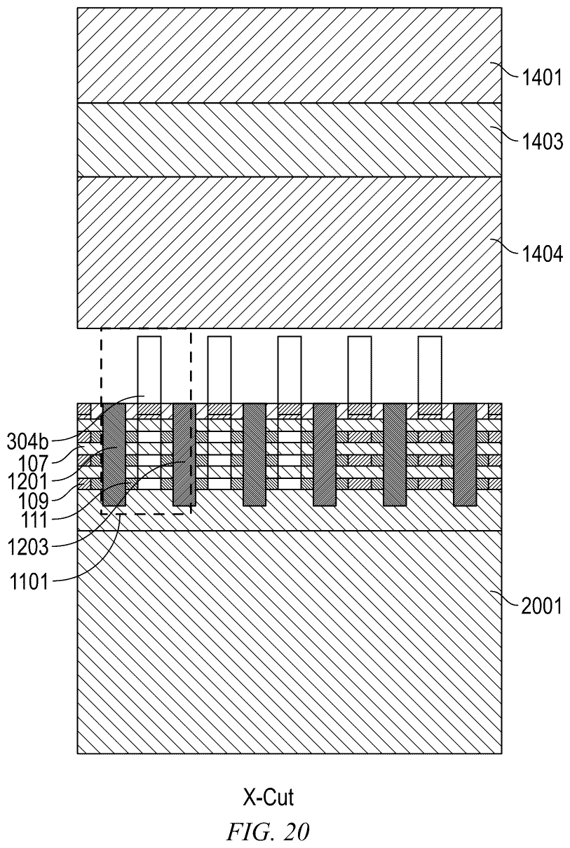

FIG. 20 illustrates the structure of FIGS. 19A and 19B after gate formation and bulk silicon removal and backside dielectric 2001 deposition. Note handling wafer 1401, bonding oxide 1403, top metal region 1404, gates 304b, SiGe nanolayers 107, Si nanolayers 109, and the inner spacers 111. Note that the standard metal gate forms on the top only of the diode structure, but wraps around the silicon nanosheets in the FET region where the SiGe has been removed. Note the p-type anode 1201 and the n-type cathode 1203.

Consider now a second exemplary process flow shown in FIGS. 21A-25. Refer initially to the views in FIGS. 21A and 21B and the view along section lines X. As shown, the mask 1302 prevents recessing of SiGe nanolayers 107. Note Si nanolayers 109. There are no inner spacers formed in this exemplary process because there is no recessing of the SiGe nanolayers.

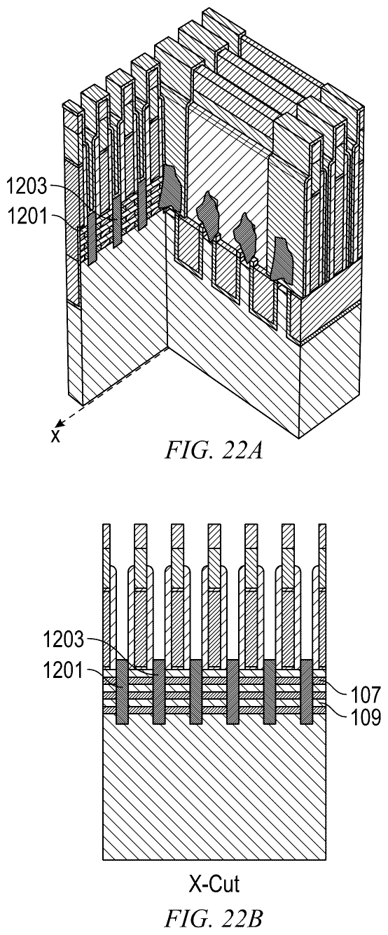

FIGS. 22A and 22B illustrate the structure of FIGS. 21A and 21B after formation of the p-type anode 1201 on one side of the SiGe/Si stacks, and the n-type cathode 1203 on the other. The anode is formed from p-FET drain-source (S/D) epitaxy and the cathode from the n-FET S/D epitaxy.

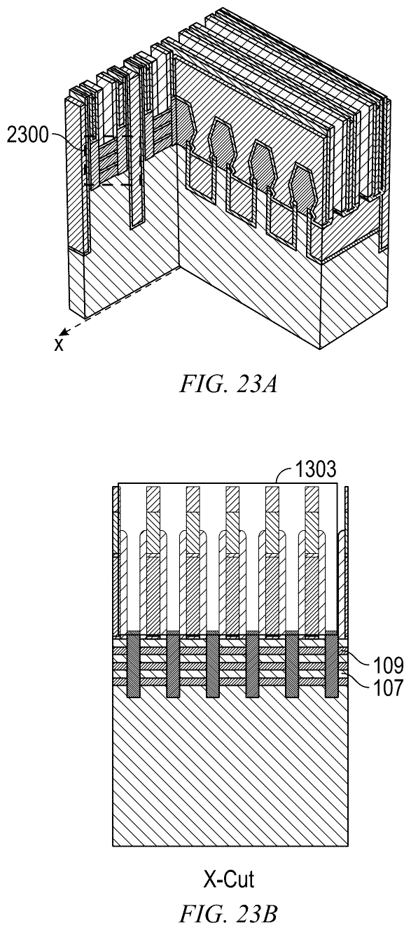

FIGS. 23A and 23B illustrate the structure of FIGS. 22A and 22B after masking, blocking, and SiGe etch. Note mask 1302, SiGe nanolayers 107, and Si nanolayers 109. Mask 1303 prevents nanosheet release in a diode area 2300.

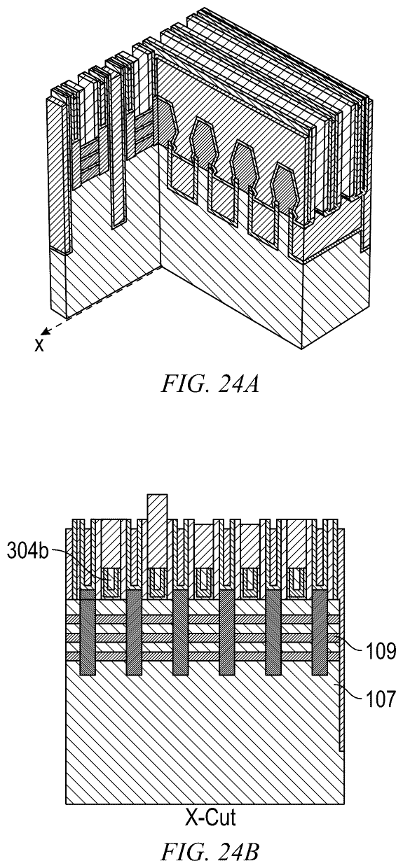

FIGS. 24A and 24B illustrate the structure of FIGS. 23A and 23B after standard metal gate formation. The gate forms only on the top of the diode structure as the SiGe has not been removed in this region. Note gates 304b, SiGe nanolayers 107, and Si nanolayers 109.

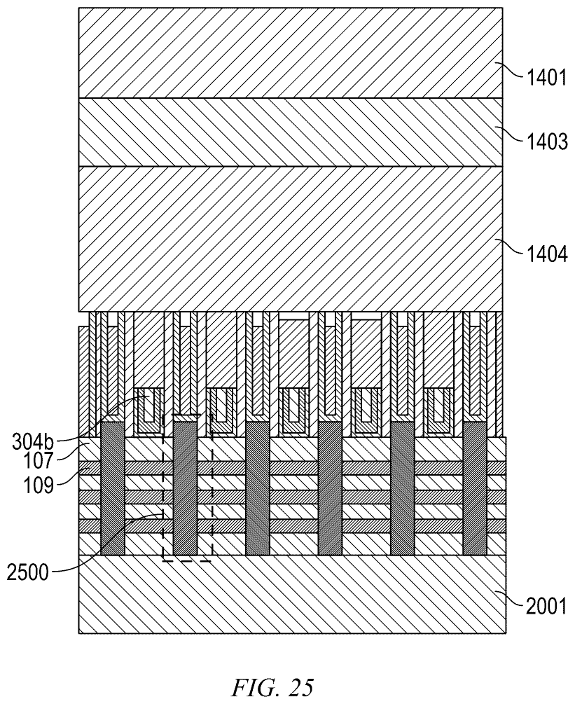

FIG. 25 illustrates the structure of FIGS. 24A and 24B after bulk silicon removal and backside dielectric 2001 deposition. Note handling wafer 1401, bonding oxide 1403, top metal region 1404, gates 304b, SiGe nanolayers 107, Si nanolayers 109. Note standard metal gate formation is on the top only of the diode structure (the gates surround the channels in the FET regions). Note region 2500 without inner spacers.

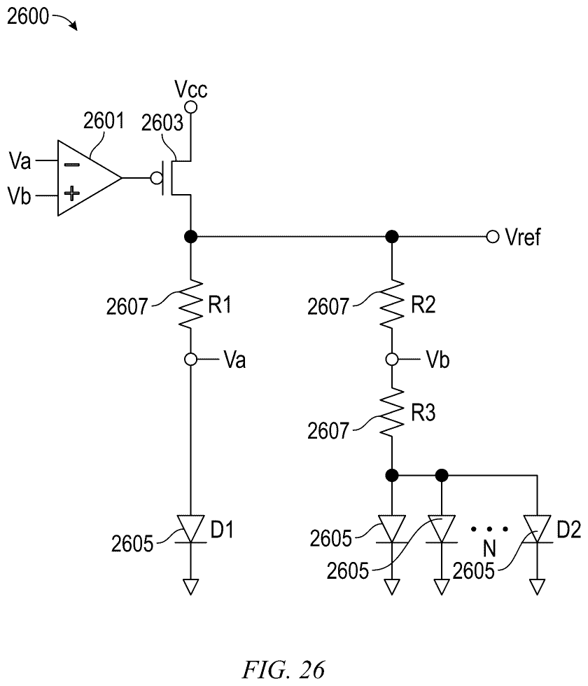

FIG. 26 illustrates an exemplary bandgap reference circuit 2600. Note the CMOS op-amp 2601, FET 2603 (in the example, a PFET), diodes 2605, and resistors 2607. Such circuits typically include a FET with its gate controlled by the output of the op-amp, VCC input to one source-drain, and a resistor/diode network on the other source-drain. In one or more embodiments, the diode(s) 2605 and FETs of the CMOS op-amp 2601 are FETs and diodes with coplanar nanolayers as described elsewhere herein. FETs and diodes with coplanar nanolayers as described elsewhere herein can be sued with any type of CMOS-compatible BGR; the BGR depicted in FIG. 26 is a non-limiting example.

One or more embodiments include a structure to enable a bandgap reference circuit in nanosheet technology with dielectric isolation 2001 or the BSPDN 405. One or more embodiments include a structure for a diode in a nanosheet technology with full dielectric isolation. One or more embodiments include using well masks to form the junction between the anode 105 and the cathode 103. One or more embodiments include a mask to prevent nanosheet release in a diode area 2300. One or more embodiments include a mask 1302 to prevent SiGe undercut and inner spacer 111 formation in the diode area 2300. One or more embodiments include alternating silicon layers (Si nanolayers 109) and SiGe layers 107 disposed between a cathode 103 and an anode 105 to form the diode. In one or more embodiments, lateral dimension x₂ is set by the FET metal gate process or the anode/cathode spacing process, whichever is more limiting. One or more embodiments include the anode 105 that is formed from the pFET source/drain (S/D) epitaxy and the cathode 103 that is formed from the nFET S/D epitaxy. One or more embodiments include a spacer 111 that is interposed between the SiGe nanolayer 107 and the epitaxy of cathode 103, and anode 105. In one or more embodiments, the SiGe nanolayers 107 and the epitaxy of cathode 103, and anode 105 abut one another. One or more embodiments include a metallic contact 904 that laterally abuts the anode 105 epitaxy over at least some vertical distance y.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary semiconductor device includes a diode structure 302 including: stacked nanolayers including alternating Si nanolayers 109 and SiGe nanolayers 107; a p-type doped anode 105 region in direct contact with the stacked nanolayers; and an n-type doped cathode 103 region in direct contact with the stacked nanolayers; and a plurality of field effect transistor (FET) structures 303. Each FET structure comprises Si nanolayers 109 that are coplanar with the Si nanolayers 109 of the diode structure.

In some cases, each FET structure 303 includes a source-drain 110 region adjacent to the Si nanolayers 109 of the corresponding FET structure.

One or more embodiments further include an interlayer dielectric, where the interlayer dielectric contacts the n-type doped cathode 103 region.

In some instances, a first one of the FET structures 303 includes inner spacers 111 stacked with the Si nanolayers 109 of the first one of the FET structures.

In some cases, a second one of the FET structures 303 includes inner spacers 111 stacked with the Si nanolayers 109 of the second one of the FET structures.

One or more embodiments further include a backside power delivery network 405 positioned below the FET structures 303 and the diode structure 302.

One or more embodiments further include a metallic contact 904 that laterally abuts at least one of the p-type doped anode 105 region or the n-type doped cathode 103 region over a vertical distance y.

In some instances, each FET structure includes a metal gate 304a that is formed all around the Si nanolayers of the corresponding FET structure 303 and wherein the diode structure 302 includes a metal gate 304b that is formed only at the top of the stacked nanolayers of the diode structure.

One or more embodiments further include an interlayer dielectric layer 309 that is in contact with the source-drain 110 regions of the FET structures.

In one or more embodiments, the SiGe nanolayers 107 of the diode structure are formed between the p-type doped anode 105 region and the n-type doped cathode 103 region.

In one or more embodiments, each FET structure 303 includes a source-drain 110 region adjacent to the Si nanolayers 109 of the corresponding FET structure, where a first source drain 110 region includes a p-FET source drain region positioned on one side of the diode structure 302.

In some cases, a second source drain 110 region includes an n-FET source drain 110 region positioned on another side of the diode structure 302.

In one or more embodiments, a lateral dimension of the diode structure 302 ranges from 20 to 200 nanometers.

Some embodiments further include a bandgap reference circuit comprising the diode structure 302 and the plurality of field effect transistor (FET) structures 303.

In another aspect, an exemplary bandgap reference circuit 2600 includes a complementary metal oxide semiconductor operational amplifier (op-amp 2601); a field effect transistor 2603 having a first source drain terminal, a second source drain terminal, and a gate coupled to an output of the operational amplifier; and a resistor-diode network coupled to the second source drain terminal. The resistor-diode network includes a plurality of resistors 2607 and a plurality of diodes 2605. At least one diode of the plurality of diodes includes stacked nanolayers including alternating Si nanolayers and SiGe nanolayers; a p-type doped anode region in direct contact with the stacked nanolayers; and an n-type doped cathode region in direct contact with the stacked nanolayers. The field effect transistor includes Si nanolayers that are coplanar with the Si nanolayers of the at least one diode.

In still another aspect, an exemplary method of forming a semiconductor device, includes providing an initial diode structure 1101 that includes a stack of SiGe nanolayers 107 that are alternatively stacked with the Si nanolayers 109; forming a p-type anode 1201 on one side of the stack, and forming an n-type cathode 1203 on the other side of the stack; and forming a plurality of field effect transistors (FETs) 303 in other regions of the semiconductor device, wherein each FET comprises SiGe nanolayers and Si nanolayers 109 that are coplanar with the Si nanolayers 109 of the initial diode structure 1101. In one or more embodiments, the FET formation and the anode and cathode formation are carried out in parallel.

One or more embodiments further include masking portions 1303 of the initial diode structure 1101 to block an SiGe etch and forming regions 2500 without inner spacers in the initial diode structure 1101.

One or more embodiments further include masking portions 1302 of the initial diode structure 1101 to block an SiGe etch and forming regions retaining the SiGe nanolayers in the initial diode structure while removing SiGe in the FETs.

One or more embodiments further include forming inner spacers 111 adjacent to the p-type anode 1201 and the n-type cathode 1203.

One or more embodiments further include forming a metal gate 304b only at the top of the stacked nanolayers of the diode structure 1101 between the p-type anode 1201 and the n-type cathode 1203; and forming gates all around the Si nanolayers 109 of the FETs.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of an exemplary lateral ideal diode for bandgap reference in nanosheet technology.

An integrated circuit in accordance with aspects of the present inventions can be employed in essentially any application and/or electronic system where one or more aspects of the exemplary lateral ideal diode for bandgap reference in nanosheet technology as disclosed herein would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. §1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor device comprising:
a diode structure including:
stacked nanolayers including alternating Si nanolayers and SiGe nanolayers;
a p-type doped anode region in direct contact with the stacked nanolayers; and
an n-type doped cathode region in direct contact with the stacked nanolayers; and
a plurality of field effect transistor (FET) structures, wherein each FET structure comprises Si nanolayers that are coplanar with the Si nanolayers of the diode structure.

2. The semiconductor device of claim 1, wherein each FET structure of the plurality of FET structures includes a source-drain region adjacent to the Si nanolayers.

3. The semiconductor device of claim 1, further including an interlayer dielectric, wherein the interlayer dielectric contacts the p-type doped anode region.

4. The semiconductor device of claim 1, further including an interlayer dielectric, wherein the interlayer dielectric contacts the n-type doped cathode region.

5. The semiconductor device of claim 1, wherein a first one of the plurality of FET structures includes inner spacers stacked with the Si nanolayers of the first one of the plurality of FET structures.

6. The semiconductor device of claim 5, wherein a second one of the plurality of FET structures includes inner spacers stacked with the Si nanolayers of the second one of the plurality of FET structures.

7. The semiconductor device of claim 1, further including a backside power delivery network positioned below the plurality of FET structures and the diode structure.

8. The semiconductor device of claim 1, further comprising a metallic contact that laterally abuts at least one of the p-type doped anode region or the n-type doped anode region over a vertical distance.

9. The semiconductor device of claim 1, wherein each FET structure includes a metal gate that is formed all around the Si nanolayers of the corresponding FET structure, and wherein the diode structure includes a metal gate that is formed only at a top of the stacked nanolayers of the diode structure.

10. The semiconductor device of claim 9, wherein each FET structure of the plurality of FET structures includes a source-drain region adjacent to the Si nanolayers, further comprising an interlayer dielectric layer that is in contact with the source-drain region of the FET structures.

11. The semiconductor device of claim 1, wherein the SiGe nanolayers of the diode structure are formed between the p-type doped anode region and the n-type doped cathode region.

12. The semiconductor device of claim 1, wherein each FET structure includes a source-drain region adjacent to the Si nanolayers of the corresponding FET structure, wherein a first source drain region includes a p-FET source drain region positioned on one side of the diode structure.

13. The semiconductor device of claim 12, wherein a second source drain region includes an n-FET source drain region positioned on another side of the diode structure.

14. The semiconductor device of claim 1, wherein a lateral dimension of the diode structure ranges from 20 to 200 nanometers.

15. A bandgap reference circuit comprising:
a complementary metal oxide semiconductor operational amplifier;
a field effect transistor having a first source drain terminal, a second source drain terminal, and a gate coupled to an output of the operational amplifier; and
a resistor-diode network coupled to the second source drain terminal, the resistor-diode network comprising a plurality of resistors and a plurality of diodes;
wherein:
at least one diode of the plurality of diodes includes:
stacked nanolayers including alternating Si nanolayers and SiGe nanolayers;
a p-type doped anode region in direct contact with the stacked nanolayers; and
an n-type doped cathode region in direct contact with the stacked nanolayers; and
the field effect transistor includes Si nanolayers that are coplanar with the Si nanolayers of the at least one diode.

16. A method of forming a semiconductor device, the method comprising:
providing an initial diode structure that includes a stack of SiGe nanolayers that are alternatively stacked with Si nanolayers;
forming a p-type anode on one side of the stack, and forming an n-type cathode on another side of the stack; and
forming a plurality of field effect transistors (FETs) in other regions of the semiconductor device, wherein each FET comprises SiGe nanolayers and Si nanolayers that are coplanar with the Si nanolayers of the initial diode structure.

17. The method of claim 16, further comprising masking portions of the initial diode structure to block an SiGe etch and forming regions, without inner spacers in the initial diode structure.

18. The method of claim 16, further comprising masking portions of the initial diode structure to block an SiGe etch and forming regions retaining the SiGe nanolayers in the initial diode structure while removing SiGe in the FETs.

19. The method of claim 16, further comprising forming inner spacers adjacent to the p-type anode and the n-type cathode.

20. The method of claim 16, further comprising forming a metal gate only at a top of the stacked nanolayers of the diode structure between the p-type anode, and the n-type cathode; and forming gates all around the Si nanolayers of the FETs.
